(19) United States
(12) Patent Application Publication
(10) Pub. No.: US 2026/0025147 A1
(43) Pub. Date: Jan. 22, 2026

(54) Successive approximation register analog-to-digital converter and digital-to-analog conversion circuit thereof

(71) Applicant: REALTEK SEMICONDUCTOR CORPORATION, Hsinchu (TW)

(72) Inventor: Shih-Hsiung HUANG, Hsinchu (TW)

(21) Appl. No.: 19/240,992

(22) Filed: Jun. 17, 2025

(30) Foreign Application Priority Data
Jul. 16, 2024 (TW) 113126612

(51) Int. Cl. H03M 1/46

(52) U.S. Cl. CPC H03M 1/46

(57) ABSTRACT

A successive approximation register analog-to-digital converter includes a digital-to-analog conversion circuit. The digital-to-analog conversion circuit includes a first set of switches and a first capacitor group. The first capacitor group samples an analog input signal during a sampling period and receives a first set of reference signals through the first set of switches during a holding period so as to accomplish charge redistribution and thereby generate a sampling-and-switching operation result. The first capacitor group includes a first subsidiary capacitor group and a second subsidiary capacitor group. Each capacitor of the first subsidiary capacitor group is composed of one or more first unit capacitor(s). Each capacitor of the second subsidiary capacitor group is composed of one or more second unit capacitor(s). The layouts of the first and the second unit capacitors are different. The designed capacitance value of the second unit capacitor is greater than that of the first unit capacitor.

### BACKGROUND OF THE INVENTION

### 1. Field of the Invention

The present disclosure relates to a digital-to-analog conversion circuit, especially to a digital-to-analog conversion circuit applicable to a successive approximation register analog-to-digital converter (SAR ADC).

### 2. Description of Related Art

FIG. 1 shows a conventional capacitor array 100 of a digital-to-analog conversion circuit applicable to a successive approximation register analog-to-digital converter (SAR ADC). As shown in FIG. 1, one end of each capacitor of the conventional capacitor array 100 is coupled to a lower electrode plate 102 while the other end is coupled to an electrode plate of a reference voltage VR or an electrode plate of a ground voltage GND through a switch 104. The conventional capacitor array 100 includes a plurality of capacitors 1C, 1C, 2C, 4C, 8C, 16C, 32C, 64C, 128C, etc., wherein 1C represents a capacitor composed of one unit capacitor, 2C represents a capacitor composed of two unit capacitors, and so on. The layout of the unit capacitor is usually determined according to the manufacturing process and/or the designer's preference. There are currently a variety of known layouts of the unit capacitor, such as the layouts of the metal-oxide-metal (MOM) unit capacitors disclosed in the applicant's U.S. Pat. Nos. 10,374,625B2, 11,810,916B2, and 11,837,597B2 and in the applicant's US patent application Publication US2022/0367447A1.

Referring to FIG. 1, each of the plurality of capacitors (i.e., 1C, 1C, 2C, 4C, 8C, 16C, 32C, 64C, 128C, etc.) of the conventional capacitor array 100 is composed of one or more identical unit capacitor(s). The advantage of this design is that: when the characteristic of the identical unit capacitor deviates from expectations (e.g., the unit capacitor's measured capacitance value is greater than its designed capacitance value) due to the manufacturing process and/or the environmental factors, each of the plurality of capacitors changes by similar or the same amount, which implies that the ratio between the measured capacitance values of any two capacitors (e.g., the ratio of the capacitor 2C's measured capacitance value 2.2 femtofarad (fF) to the capacitor 8C's measured capacitance value 8.8fF) of the plurality of capacitors will be equal to or close to the ratio between the designed capacitance values of the two capacitors (e.g., the ratio of the capacitor 2C's designed capacitance value 2fF to the capacitor 8C's designed capacitance value 8fF). In this specification, a designed capacitance value is a value determined according to implementation needs in a development phase, and a measured capacitance value is a value obtained in a known/self-developed measurement method.

However, compared with mature processes, an advanced process (such as a 7 nanometer (nm) process or a more advanced process) has more restrictions on the layout of metal traces. For example: the routing direction of the metal traces located on the first metal layer of an IC can only be the lateral direction (hereinafter referred to as X direction); the routing direction of the metal traces located on the second metal layer of the IC can only be the longitudinal direction (hereinafter referred to as Y direction); the routing direction of the metal traces located on the third metal layer of the IC can be the X direction or the Y direction, and choosing the X direction is advantageous to reduce the spacing between metal traces; the routing direction of the metal traces located on the fourth metal layer of the IC can be the X direction or the Y direction, and choosing the X direction is advantageous to reduce the spacing between metal traces; and the routing direction of the metal traces located on the fifth metal layer of the IC can be the X direction or the Y direction, and choosing either direction does not affect the spacing between metal traces. Such restrictions restrict the layout of an MOM unit capacitor, thereby significantly increasing the cost or the design difficulty of the conventional capacitor array 100 whose capacitors are based on the same MOM unit capacitor.

For example, when using a process design kit (PDK) of an advanced process to design the conventional capacitor array 100, the minimum designed capacitance value of a unit capacitor of the conventional capacitor array 100 may be at least 1 fF (the value of 1 fF is just an example; the value of 1 fF may decrease with advancements in the manufacturing process), which is relatively large, causes the conventional capacitor array 100 to consume a lot of circuit area, and causes the circuits cooperating with the conventional capacitor array 100 (e.g., the switches 104 and the driving circuits thereof (not shown) in FIG. 1) to consume a lot of circuit area; consequently, this results in a high cost.

Further, for example, the unit capacitor (e.g., the MOM unit capacitor shown in any of FIG. 1a, 1b, and 2 of the applicant's U.S. Pat. No. 11,810,916B2) of each capacitor of the conventional capacitor array 100 may have a small capacitance value (e.g., 0.25fF) to avoid consuming a large amount of circuit area; however, this unit capacitor includes metal traces in the X direction and metal traces in the Y direction on the same metal layer, and thus this unit capacitor cannot be formed on certain metal layers (e.g., the aforementioned first and second metal layers) when it is manufactured with an advanced process; consequently, this greatly increases the difficulty in design.

### SUMMARY OF THE INVENTION

One objective of the present disclosure is to propose a successive approximation register analog-to-digital converter (SAR ADC) and the digital-to-analog conversion circuit thereof as an improvement over the prior art.

An embodiment of the SAR ADC of the present disclosure includes a digital-to-analog conversion circuit, a comparison circuit, and a control circuit. The digital-to-analog conversion circuit is configured to receive an analog input signal during a sampling period and receive a first set of reference signals according to a first set of switch control signals during a holding period so as to accomplish charge redistribution and thereby output a sampling-and-switching operation result. The digital-to-analog conversion circuit includes a first set of switches and a first capacitor group. The first set of switches is configured to determine a coupling state of each capacitor of a first capacitor group according to the first set of switch control signals, wherein the first set of reference signals received by the digital-to-analog conversion circuit varies with a change in the first set of switch control signals. The first capacitor group is configured to sample the analog input signal during the sampling period and receive the first set of reference signals through the first set of switches during the holding period to accomplish the charge redistribution. The first capacitor group includes a first subsidiary capacitor group and a second subsidiary capacitor group. Each capacitor of the first subsidiary capacitor group is composed of one or more identical unit capacitor(s) (i.e., one first unit capacitor or a plurality of first unit capacitors); and each capacitor of the second subsidiary capacitor group is composed of one or more identical unit capacitor(s) (i.e., one second unit capacitor or a plurality of second unit capacitors). The layout of the second unit capacitor is different from the layout of the first unit capacitor; and the designed capacitance value of the second unit capacitor is greater than the designed capacitance value of the first unit capacitor. The comparison circuit is configured to generate a comparison result according to the sampling-and-switching operation result. The control circuit is configured to generate the first set of switch control signals and a digital output signal according to the comparison result.

An embodiment of the digital-to-analog conversion circuit of the present disclosure includes a first set of switches and a first capacitor group. The first capacitor group is configured to receive an analog input signal during a sampling period and receive a first set of reference signals through the first set of switches during a holding period so as to accomplish charge redistribution and thereby output a sampling-and-switching operation result. The first capacitor group includes a first subsidiary capacitor group and a second subsidiary capacitor group. Each capacitor of the first subsidiary capacitor group is composed of one or more identical unit capacitor(s) (i.e., one first unit capacitor or a plurality of first unit capacitors). Each capacitor of the second subsidiary capacitor group is composed of one or more identical unit capacitor(s) (i.e., one second unit capacitor or a plurality of second unit capacitors). The layout of the second unit capacitor is different from the layout of the first unit capacitor, and the designed capacitance value of the second unit capacitor is greater than the designed capacitance value of the first unit capacitor.

These and other objectives of the present invention will no doubt become obvious to those of ordinary skill in the art after reading the following detailed description of the preferred embodiments that are illustrated in the various figures and drawings.

### BRIEF DESCRIPTION OF THE DRAWINGS

FIG. 1 shows a conventional capacitor array of a digital-to-analog conversion circuit applicable to a successive approximation register analog-to-digital converter (SAR ADC).

FIG. 2 shows an embodiment of the SAR ADC of the present disclosure.

FIG. 3 shows an embodiment of the digital-to-analog conversion circuit of FIG. 2.

FIG. 4 shows an embodiment of the control circuit of FIG. 2.

### DETAILED DESCRIPTION OF THE PREFERRED EMBODIMENTS

This specification discloses a successive approximation register analog-to-digital converter (SAR ADC) and a digital-to-analog conversion circuit (DAC) applicable to the SAR ADC. The SAR ADC and the DAC consume less circuit area, and the ratio between the capacitance values of any two capacitors of the DAC can be as expected under the influence of processes and environmental factors.

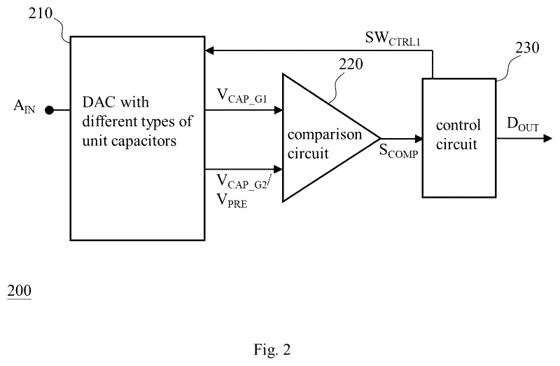

FIG. 2 shows an embodiment of the SAR ADC of the present disclosure. The SAR ADC 200 of FIG. 2 includes a DAC 210 including different types of unit capacitors, a comparison circuit 220, and a control circuit 230. The background knowledge of a general SAR ADC is found in the applicant's U.S. Pat. No. 10,171,097B1 and other publications about SAR ADCs, and is not described in detail here.

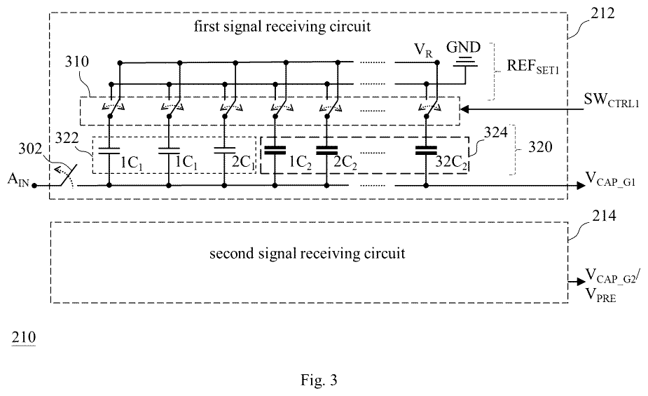

Referring to FIG. 2, the DAC 210 is configured to receive an analog input signal Aix during a sampling period and then receive a first set of reference signals REF_{SET1} (as shown in FIG. 3) according to a first set of switch control signals SW_{CTRL1} during a holding period so as to output a sampling-and-switching operation result V_{CAP_G1} through charge redistribution.

FIG. 3 shows an embodiment of the DAC 210 including a first signal receiving circuit 212. The first signal receiving circuit 212 includes a first sampling control switch 302, a first set of switches 310, and a first capacitor group 320. The first sampling control switch 302 is turned on during the sampling period to allow the first capacitor group 320 to sample the analog input signal A_{IN}. The first sampling control switch 302 is turned off during the holding period so that the first capacitor group 320 performs charge redistribution according to the first set of reference signals REF_{SET1}. The first set of switches 310 is configured to determine the coupling state of each capacitor of the first capacitor group 320 according to the first set of switch control signals SW_{CTRL1}, wherein the first set of reference signals REF_{SET1} received by the first capacitor group 320 varies with the change in the first set of switch control signals SW_{CTRL1}. More specifically, the switches of the first set of switches 310 cooperate with the capacitors of the first capacitor group 320 respectively, wherein one end of each switch is coupled to the lower electrode plate of a corresponding capacitor while the other end is coupled to an electrode plate of a reference voltage VR, an electrode plate of another reference voltage such as a ground voltage GND, or an electrode plate of a specific voltage such as a common-mode voltage V_{CM} (not shown in the figures) or a maximum supply voltage V_{SS} (not shown in the figures) according to the first set of switch control signals SW_{CTRL1}. Therefore, the first set of reference signals REF_{SET1} received by the first capacitor group 320 through the first set of switches 310 is composed of, for example, I reference voltages VR and J ground voltages GND, wherein the values of I and J are determined by the first set of switch control signals SW_{CTRL1} generated by the control circuit 230 and will vary with the changes in the first set of switch control signals SW_{CTRL1}. It is noted that in practice, the forementioned lower electrode plate may receive the reference voltage VR, the another reference voltage, and the specific voltage through three switches respectively.

Referring to FIG. 3, the first capacitor group 320 includes a first subsidiary capacitor group 322 (e.g., a capacitor group composed of 1C1, 1C1, and 2C1) and a second subsidiary capacitor group 324 (e.g., a capacitor group composed of 1C2, 2C2, 4C2, 8C2, 16C2, and 32C2). Each capacitor of the first subsidiary capacitor group 322 is composed of one or more identical unit capacitor(s) (i.e., one or more first unit capacitor(s) C1); in an implementation example, the first subsidiary capacitor group 322 includes a first capacitor and a second capacitor, wherein the first capacitor is composed of P first unit capacitor(s) C1 and the second capacitor is composed of Q first unit capacitor(s) C1, both the P and the Q are positive integers, and the P is different from the Q; in an implementation example, the first unit capacitor C1 has the minimum capacitance value among all the capacitors of the first subsidiary capacitor group 322. Each capacitor of the second subsidiary capacitor group 324 is composed of one or more identical unit capacitor(s) (i.e., one or more second unit capacitor(s) C2); in an implementation example, the second subsidiary capacitor group 324 includes a third capacitor and a fourth capacitor, wherein the third capacitor is composed of X second unit capacitor(s) C2 and the fourth capacitor is composed of Y second unit capacitor(s) C2, both the X and the Y are positive integers, and the X is different from the Y; in an implementation example, the second unit capacitor C2 has the minimum capacitance value among all the capacitors of the second subsidiary capacitor group 324.

It is noted that the layout of the second unit capacitor C2 may be different from the layout of the first unit capacitor C1, and the capacitance value of the second unit capacitor C2 (i.e., any of the designed and the measured capacitance values of C2) is greater than the capacitance value of the first unit capacitor C1 (i.e., any of the designed and the measured capacitance values of C1). In an implementation example, the designed/measured capacitance value of the second unit capacitor C2 (e.g., 1fF) is greater than the designed/measured capacitance value of any capacitor of the first subsidiary capacitor group 322. In an implementation example, the designed capacitance value of the second unit capacitor C2 (e.g., 1fF)) is four times the designed capacitance value of the first unit capacitor C1 (e.g., 0.25fF). In an implementation example, the measured capacitance value of the second unit capacitor C2 is greater than twice the measured capacitance value of the first unit capacitor C1.

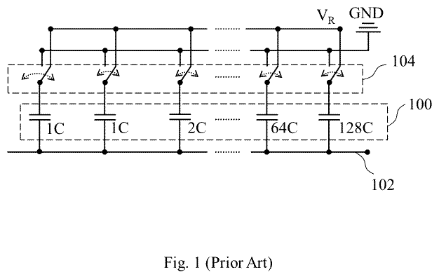

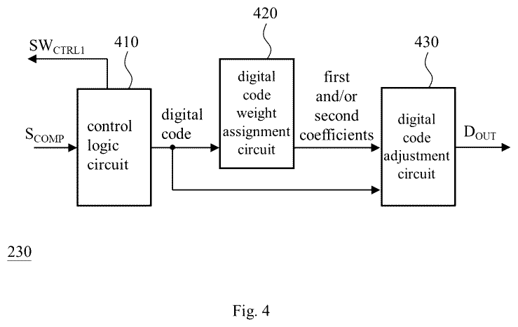

Referring to FIG. 3, in an embodiment, the layout of the first unit capacitor C1 is any of the layouts of the metal-oxide-metal (MOM) capacitors shown in FIG. 1a, 1b, and 2 of the applicant's U.S. Pat. No. 11,810,916B2 while the layout of the second unit capacitor C2 is one of the following:
(1) any of the layouts of the MOM capacitors shown in FIGS. 3a, 3b, and 4 of the applicant's US patent U.S. Pat. No. 11,810,916B2;
(2) the layout of the MOM capacitor shown in FIG. 2 of the applicant's US patent application publication US2022/0367447A1; and
(3) any of the layouts of the MOM capacitors shown in FIGS. 2a, 2b, 2c, 3, and 4 of the applicant's U.S. Pat. No. 11,837,597B2.

It is noted that the first subsidiary capacitor group 322 using the first unit capacitor C1 as the basic unit can be fabricated on the fourth or the fifth metal layer of an IC, and the second subsidiary capacitor group 324 using the second unit capacitor C2 as the basic unit can be fabricated on two or more layers of the first, the second, and the third metal layers of the IC; however, the implementation of the present invention is not limited thereto. The definition of the metal layers of an IC and the limitations on their utilization are common knowledge in the art. It is also noted that those having ordinary skill in the art can refer to the present disclosure to adopt any of other known or self-developed MOM capacitor layouts as the layout of the first unit capacitor C1 and/or the layout of the second unit capacitor C2 according to their implementation needs.

Referring to FIG. 3, the DAC 210 further includes a second signal receiving circuit 214. When the architecture of the DAC 210 is a differential signal architecture, the function, operation, and configuration of the second signal receiving circuit 214 are similar to those of the first signal receiving circuit 212; more specifically, the second signal receiving circuit 214 includes a second sampling control switch (not shown in the figures) whose function and operation are identical/similar to the first sampling control switch 302, a second set of switches (not shown in the figures) whose function and operation are identical/similar to the first set of switches 310, and a second capacitor group and its subsidiary capacitor groups (not shown in the figures) whose function and operation are identical/similar to the first capacitor group 320 and its subsidiary capacitor groups. Based on the above, the second signal receiving circuit 214 is configured to generate another sampling-and-switching operation result V_{CAP_G2} to the comparison circuit 220; the analog input signal Aux received by the first signal receiving circuit 212 is a noninverting signal of a differential signal while and the analog input signal (not shown in the figure) received by the second signal receiving circuit 214 is an inverting signal of the differential signal. When the architecture of the DAC 210 is a single-ended signal architecture, the second signal receiving circuit 214 is configured to provide a predetermined signal V_{PRE} (e.g., a signal of a predetermined voltage) for the comparison circuit 220.

Referring to FIG. 2, the comparison circuit 220 is configured to generate a comparison result S_{COMP} according to the sampling-and-switching operation result V_{CAP_G1} and one of the sampling-and-switching operation result V_{CAP_G2} and the predetermined signal V_{PRE}. Since the comparison circuit 220 alone can be implemented by using known technology (e.g., a general comparator) or other self-developed technology (e.g., a self-developed comparator), its details are omitted here.

Referring to FIG. 2, the control circuit 230 is configured to generate the first set of switch control signals SW_{CTRL1} and a digital output signal D_{OUT} according to the comparison result S_{COMP}. An embodiment of the control circuit 230 is, for example, a first embodiment or a second embodiment as described below.
(1) In the first embodiment, the control circuit 230 alone is implemented by using known technology (e.g., a general control-logic circuit of an SAR ADC) or other self-developed technology (e.g., a self-developed control-logic circuit applicable to an SAR ADC).
(2) In the second embodiment, considering that the response of the first unit capacitor C1 of the first subsidiary capacitor group 322 to the changes in process and environmental factors may be significantly different from the response of the second unit capacitor C2 of the second subsidiary capacitor group 324 to the changes in the same process and environmental factors, the control circuit 230 makes adjustments to balance these responses.

In an implementation example: an adjusted capacitance value of the first unit capacitor C1 is obtained by multiplying the measured capacitance value, which can be determined by a known or self-developed measurement method, of the first unit capacitor C1 by a first coefficient; a ratio of the adjusted capacitance value of the first unit capacitor C1 to the measured capacitance value of the second unit capacitor C2 meets a predetermined ratio; and the control circuit 230 determines the digital output signal D_{OUT} according to the first coefficient. More specifically, during the holding period, when a change in the first set of switch control signals SW_{CTRL1} changes the coupling state(s) of M first unit capacitors C1 of the first subsidiary capacitor group 322, the control circuit 230 adjusts a digital code corresponding to the M according to the first coefficient and thereby generates a part of the digital output signal D_{OUT}, wherein the M is a positive integer not greater than the number of all first unit capacitors C1 of the first subsidiary capacitor group 322.

In an implementation example: an adjusted capacitance value of the second unit capacitor C2 is obtained by multiplying the measured capacitance value of the second unit capacitor C2 by a second coefficient; a ratio of the adjusted capacitance value of the second unit capacitor C2 to the measured capacitance value of the first unit capacitor C1 meets a predetermined ratio; and the control circuit 230 determines the digital output signal D_{OUT} according to the second coefficient. More specifically, during the holding period, when a change in the first set of switch control signals SW_{CTRL1} changes the coupling state(s) of N second unit capacitors C2 of the second subsidiary capacitor group 322, the control circuit 230 adjusts a digital code corresponding to the N according to the second coefficient and thereby generates a part of the digital output signal D_{OUT}, wherein the N is a positive integer not greater than the number of all second unit capacitors C2 of the second subsidiary capacitor group 324.

It is noted that each of the above-mentioned predetermined ratios is determined according to the difference between the responses to the changes in process and environmental factors. It is also noted that the first coefficient and/or the second coefficient can be determined or adjusted by observing the characteristic of the SAR ADC 200 (e.g., at least one of the differential nonlinearity (DNL), the integral nonlinearity (INL), and the effective number of bits (ENOB)).

Based on the second embodiment, an embodiment of the control circuit 230 is shown in FIG. 4 and includes a control-logic circuit 410, a digital code weight assignment circuit 420, and a digital code adjustment circuit 430. The control-logic circuit 410 is, for example, a known or self-developed control-logic circuit of an SAR ADC. The control-logic circuit 410 is configured to generate the first set of switch control signals SW_{CTRL1} according to the comparison result S_{COMP}, and further configured to generate the digital code corresponding to the aforementioned number(s) M and/or N. The digital code weight assignment circuit 420 is configured to assign the first coefficient and/or the second coefficient appropriate for the digital code. The digital code adjustment circuit 430 is configured to adjust the digital code according to the first coefficient and/or the second coefficient.

It is noted that if an implementation is practicable, people having ordinary skill in the art can selectively implement some or all of the technical features in any of the foregoing embodiments or selectively implement a combination of some or all of the technical features in several of the foregoing embodiments to implement the present invention. It is also noted that the DAC of the present disclosure (e.g., the DAC 210 in FIG. 3) can be applied to the SAR ADC 200 of FIG. 2 or applied to other devices, if practicable.

To sum up, the SAR ADC and the DAC thereof of the present disclosure can reduce the consumption of circuit area and ensure that the ratio between the capacitance values of any two capacitors of the DAC is as expected.

The aforementioned descriptions represent merely the preferred embodiments of the present invention, without any intention to limit the scope of the present invention thereto. Various equivalent changes, alterations, or modifications based on the claims of the present invention are all consequently viewed as being embraced by the scope of the present invention.

What is claimed is:

1. A successive approximation register analog-to-digital converter (SAR ADC) comprising:
a digital-to-analog conversion circuit configured to receive an analog input signal during a sampling period and receive a first set of reference signals according to a first set of switch control signals during a holding period so as to accomplish charge redistribution and thereby output a sampling-and-switching operation result, the digital-to-analog conversion circuit including:
a first set of switches configured to determine a coupling state of each capacitor of a first capacitor group according to the first set of switch control signals, wherein the first set of reference signals received by the digital-to-analog conversion circuit varies with a change in the first set of switch control signals; and
the first capacitor group configured to sample the analog input signal during the sampling period and receive the first set of reference signals through the first set of switches during the holding period so as to accomplish the charge redistribution, the first capacitor group including:
a first subsidiary capacitor group, wherein each capacitor of the first subsidiary capacitor group is composed of one or more first unit capacitor(s); and
a second subsidiary capacitor group, wherein each capacitor of the second subsidiary capacitor group is composed of one or more second unit capacitor(s), a layout of the second unit capacitor is different from a layout of the first unit capacitor, and a designed capacitance value of the second unit capacitor is greater than a designed capacitance value of the first unit capacitor;
a comparison circuit configured to generate a comparison result according to the sampling-and-switching operation result; and
a control circuit configured to generate the first set of switch control signals and a digital output signal according to the comparison result.

2. The SAR ADC of claim 1, wherein the first unit capacitor has a minimum capacitance value among all capacitors of the first subsidiary capacitor group and the second unit capacitor has a minimum capacitance value among all capacitors of the second subsidiary capacitor group.

3. The SAR ADC of claim 1, wherein the designed capacitance value of the second unit capacitor is greater than twice the designed capacitance value of the first unit capacitor.

4. The SAR ADC of claim 1, wherein:
the first subsidiary capacitor group includes a first capacitor and a second capacitor, the first capacitor is composed of P first unit capacitor(s), the second capacitor is composed of Q first unit capacitor(s), the P and the Q are positive integers, and the P is different from the Q; and
the second subsidiary capacitor group includes a third capacitor and a fourth capacitor, the third capacitor is composed of X second unit capacitor(s), the fourth capacitor is composed of Y second unit capacitor(s), the X and the Y are positive integers, and the X is different from the Y.

5. The SAR ADC of claim 1, wherein the designed capacitance value of the second unit capacitor is greater than a designed capacitance value of any capacitor of the first subsidiary capacitor group.

6. The SAR ADC of claim 1, wherein an adjusted capacitance value of the first unit capacitor is equal to a product of a measured capacitance value of the first unit capacitor and a first coefficient, a ratio of the adjusted capacitance value of the first unit capacitor to a measured capacitance value of the second unit capacitor meets a predetermined ratio, and the control circuit determines the digital output signal according to the first coefficient.

7. The SAR ADC of claim 6, wherein when a single change in the first set of switch control signals changes a coupling state of M first unit capacitor(s) of the first subsidiary capacitor group during the holding period, the control circuit adjusts a digital code corresponding to the M according to the first coefficient and thereby generates a part of the digital output signal, in which the M is a positive integer not greater than a number of all first unit capacitor(s) of the first subsidiary capacitor group.

8. The SAR ADC of claim 7, wherein the control circuit includes:
a control-logic circuit configured to generate the first set of switch control signals according to the comparison result and generate the digital code corresponding to the M;
a digital code weight assignment circuit configured to assign the first coefficient appropriate for the digital code; and
a digital code adjustment circuit configured to adjust the digital code according to the first coefficient.

9. The SAR ADC of claim 1, wherein an adjusted capacitance value of the second unit capacitor is equal to a product of a measured capacitance value of the second unit capacitor and a second coefficient, a ratio of the adjusted capacitance value of the second unit capacitor to a measured capacitance value of the first unit capacitor meets a predetermined ratio, and the control circuit determines the digital output signal according to the second coefficient.

10. The SAR ADC of claim 9, wherein when a single change in the first set of switch control signals changes a coupling state of N second unit capacitor(s) of the second subsidiary capacitor group during the holding period, the control circuit adjusts a digital code corresponding to the N according to the second coefficient and thereby generates a part of the digital output signal, in which the N is a positive integer not greater than a number of all second unit capacitor(s) of the second subsidiary capacitor group.

11. The SAR ADC of claim 10, wherein the control circuit includes:
a control-logic circuit configured to generate the first set of switch control signals according to the comparison result and generate the digital code corresponding to the N;
a digital code weight assignment circuit configured to assign the second coefficient appropriate for the digital code; and
a digital code adjustment circuit configured to adjust the digital code according to the second coefficient.

12. The SAR ADC of claim 1, wherein the analog input signal is a differential signal composed of a noninverting signal and an inverting signal, the first capacitor group is configured to sample the noninverting signal during the sampling period, the analog-to-digital conversion circuit further includes a second capacitor group configured to sample the inverting signal during the sampling period, and the second capacitor group includes:
a third subsidiary capacitor group, wherein each capacitor of the third subsidiary capacitor group includes one or more third unit capacitor(s), and the third unit capacitor is equivalent to the first unit capacitor; and
a fourth subsidiary capacitor group, wherein each capacitor of the fourth subsidiary capacitor group includes one or more fourth unit capacitor(s), and the fourth unit capacitor is equivalent to the second unit capacitor.

13. A digital-to-analog conversion circuit comprising a first set of switches and a first capacitor group, wherein:
the first capacitor group is configured to receive an analog input signal during a sampling period and then receive a first set of reference signals through the first set of switches during a holding period so as to accomplish charge redistribution and thereby output a sampling-and-switching operation result, the first capacitor group including:
a first subsidiary capacitor group, wherein each capacitor of the first subsidiary capacitor group is composed of one or more first unit capacitor(s); and
a second subsidiary capacitor group, wherein each capacitor of the second subsidiary capacitor group is composed of one or more second unit capacitor(s), a layout of the second unit capacitor is different from a layout of the first unit capacitor, and a designed capacitance value of the second unit capacitor is greater than a designed capacitance value of the first unit capacitor.

14. The digital-to-analog conversion circuit of claim 13, wherein the first unit capacitor has a minimum capacitance value among all capacitors of the first subsidiary capacitor group and the second unit capacitor has a minimum capacitance value among all capacitors of the second subsidiary capacitor group.

15. The digital-to-analog conversion circuit of claim 13, wherein the designed capacitance value of the second unit capacitor is greater than twice the designed capacitance value of the first unit capacitor.

16. The digital-to-analog conversion circuit of claim 13, wherein:
the first subsidiary capacitor group includes a first capacitor and a second capacitor, the first capacitor is composed of P first unit capacitor(s), the second capacitor is composed of Q first unit capacitor(s), the P and the Q are positive integers, and the P is different from the Q; and
the second subsidiary capacitor group includes a third capacitor and a fourth capacitor, the third capacitor is composed of X second unit capacitor(s), the fourth capacitor is composed of Y second unit capacitor(s), the X and the Y are positive integers, and the X is different from the Y.

17. The digital-to-analog conversion circuit of claim 13, wherein the designed capacitance value of the second unit capacitor is greater than a designed capacitance value of any capacitor of the first subsidiary capacitor group.

18. The digital-to-analog conversion circuit of claim 13, wherein an adjusted capacitance value of the first unit capacitor is equal to a product of a measured capacitance value of the first unit capacitor and a first coefficient, a ratio of the adjusted capacitance value of the first unit capacitor to a measured capacitance value of the second unit capacitor meets a predetermined ratio, and the control circuit determines the digital output signal according to the first coefficient.

19. The digital-to-analog conversion circuit of claim 13, wherein an adjusted capacitance value of the second unit capacitor is equal to a product of a measured capacitance value of the second unit capacitor and a second coefficient, a ratio of the adjusted capacitance value of the second unit capacitor to a measured capacitance value of the first unit capacitor meets a predetermined ratio, and the control circuit determines the digital output signal according to the second coefficient.

20. The digital-to-analog conversion circuit of claim 13, wherein the analog input signal is a differential signal composed of a noninverting signal and an inverting signal, the first capacitor group is configured to sample the noninverting signal during the sampling period, the analog-to-digital conversion circuit further includes a second capacitor group configured to sample the inverting signal during the sampling period, and the second capacitor group includes:
a third subsidiary capacitor group, wherein each capacitor of the third subsidiary capacitor group includes one or more third unit capacitor(s), and the third unit capacitor is equivalent to the first unit capacitor; and
a fourth subsidiary capacitor group, wherein each capacitor of the fourth subsidiary capacitor group includes one or more fourth unit capacitor(s), and the fourth unit capacitor is equivalent to the second unit capacitor.
